(19) United States
(12) Patent Application Publication
(10) Pub. No.: US 2023/0235252 A1
(43) Pub. Date: Jul. 27, 2023

(54) Use of a Composition Consisting of Ammonia and an Alkanol for Avoiding Pattern Collapse When Treating Patterned Materials with Line-Space Dimensions of 50 NM or Below

(71) Applicant: BASF SE, Ludwigshafen am Rhein (DE)

(72) Inventors: Chi Yueh KAO, Taoyuan (TW); Mei Chin SHEN, Taoyuan (TW); Daniel LOEFFLER, Ludwigshafen (DE); Andreas KLIPP, Ludwigshafen (DE); Haci Osman GUEVENC, Ludwigshafen (DE)

(21) Appl. No.: 17/999,734

(22) PCT Filed: May 12, 2021
(86) PCT No.: PCT/EP2021/062618

§ 371 Date: Nov. 23, 2022

(30) Foreign Application Priority Data
May 27, 2020 (EP) 20176834.8

(51) Int. Cl. C11D 7/04; C11D 7/50; C11D 11/00; H01L 21/02

(52) U.S. Cl. CPC C11D 7/04; C11D 7/5022; C11D 11/0047; H01L 21/02063

(57) ABSTRACT

Described herein is a method of using a composition including 0.1 to 3% by weight ammonia and a C₁ to C₄ alkanol. The method includes using the composition for anti-pattern collapse treatment of a substrate including patterned material layers having line-space dimensions with a line width of 50 nm or less, aspect ratios of greater than or equal to 4, or a combination thereof.

Use of a composition consisting of ammonia and an alkanol for avoiding pattern collapse when treating patterned materials with line-space dimensions of 50 nm or below.

The present invention is directed to the use of a composition for manufacturing integrated circuits devices, optical devices, micromachines and mechanical precision devices, in particular for avoiding pattern collapse.

### BACKGROUND OF THE INVENTION

In the process of manufacturing ICs with LSI, VLSI and ULSI, patterned material layers like patterned photoresist layers, patterned barrier material layers containing or consisting of titanium nitride, tantalum or tantalum nitride, patterned multi-stack material layers containing or consisting of stacks e.g. of alternating polysilicon and silicon dioxide or silicon nitride layers, and patterned dielectric material layers containing or consisting of silicon dioxide or low-k or ultra-low-k dielectric materials are produced by photolithographic techniques. Nowadays, such patterned material layers comprise structures of dimensions even below 22 nm with high aspect ratios.

Irrespective of the exposure techniques the wet chemical processing of small patterns however involves a plurality of problems. As technologies advance and dimension requirements become stricter and stricter, patterns are required to include relatively thin and tall structures or features of device structures i.e., features having a high aspect ratio, on the substrate. These structures may suffer from bending and/or collapsing, in particular, during the spin dry process, due to excessive capillary forces of the liquid or solution of the rinsing liquid deionized water remaining from the chemical rinse and spin dry processes and being disposed between adjacent patterned structures.

Due to the shrinkage of the dimensions, the removal of particles and plasma etch residues in order to achieve a defect free patterned structure becomes also a critical factor. This does apply to photoresist patterns but also to other patterned material layers, which are generated during the manufacture of integrated circuits, electronic data storage media, optical devices, micromachines and mechanical precision devices.

WO 2012/027667 A2 discloses a method of modifying a surface of a high aspect ratio feature by contacting the surface of the high aspect ratio feature with an additive composition to produce a modified surface, wherein forces acting on the high aspect ratio feature when a rinse solution is in contact with the modified surface are sufficiently minimized to prevent bending or collapse of the high aspect ratio feature at least during removal of the rinse solution or at least during drying of the high aspect ratio feature. A variety of solvents, including isopropanol, but no esters are mentioned. With 4-methyl-2-pentanol and tripropylene glycol methyl ether (TPGME) or isopropanol and TPGME also combinations of solvents are disclosed.

WO 2019/086374 A discloses a non-aqueous composition for anti pattern collapse cleaning comprising siloxane-type additives. Preferably, the solvent essentially consists of one or more organic solvents, which may be protic or aprotic organic solvents. Preferred are one or more polar protic organic solvents, most preferred are single polar protic organic solvents like isopropanol.

WO 2019/224032 A discloses a non-aqueous composition for anti pattern collapse cleaning comprising a C₁ to C₆ alkanol and a carboxylic acid ester for treating substrates comprising patterns having line-space dimensions with a line width of 50 nm or below and aspect ratios of 4 and more.

US 2017/17008 A discloses a pattern treatment composition comprising a polymer comprising a surface attachment group for forming a bond with the surface of the patterned feature and a solvent and a second a pattern treatment composition that is different from the first one. Besides many other combinations, the solvents may be a combination of n-butylacetate and isopropanol.

Unpublished European patent application No. 19168153.5 discloses a non-aqueous composition for treating substrates having patterned material layers having line-space dimensions with a line width of 50 nm or below, aspect ratios of greater or equal 4 or a combination thereof comprising an organic protic solvent, ammonia, and a non-ionic H-silane additive.

However, these compositions either still suffer from high pattern collapse in sub 50 nm, particularly sub 22 nm structures, or troublesome residues of non-volatile additives remain on the surface of the structured substrates to be treated.

It is an object of the present invention to provide a method for manufacturing integrated circuits for nodes of 50 nm and lower, in particular for nodes of 32 nm and lower and, especially, for nodes of 22 nm and lower, which method no longer exhibits the disadvantages of prior art manufacturing methods.

In particular, the compounds according to the present invention shall allow for the chemical rinse of patterned material layers comprising patterns with a high aspect ratio and line-space dimensions with a line width of 50 nm and less, in particular, of 32 nm and less, especially, of 22 nm and less, without causing pattern collapse.

### SUMMARY OF THE INVENTION

Surprisingly it was found that, starting from unpublished European patent application No.

19168153.5, it is possible to remove the silane without significantly jeopardizing the pattern collapse rates, and, due to the volatility of its components, can be completely removed from the surface of the substrate very easily. Particularly it was found that a simple two-component composition essentially consisting of ammonia and a C₁ to C₄ alkanol still provides low pattern collapse rates. On the other hand, it was found that the multiple solvent compositions disclosed in WO 2019/224032 A provide a less effective pattern collapse reduction on HARS structures, particularly silicon HARS structures than those according to the present invention.

One embodiment of the present invention is the use of a composition essentially consisting of

(a) 0.1 to 3% by weight ammonia; and
(b) a C₁ to C₄ alkanol
for anti-pattern collapse treatment of a substrate comprising patterned material layers having line-space dimensions with a line width of 50 nm or below, aspect ratios of greater or equal 4, or a combination thereof.

Another embodiment of the present invention is a method for manufacturing integrated circuit devices, electronic data storage devices, optical devices, micromachines and mechanical precision devices, the said method comprising the steps of
(a) providing a substrate having patterned material layers having line-space dimensions with a line width of 50 nm or below, aspect ratios of greater or equal 4, or a combination thereof,
(b) contacting the substrate with an aqueous pretreatment composition comprising 0.1 to 2% by weight HF, preferably 0.25 to 1% by weight HF;
(c) removing the aqueous composition from the substrate;
(d) contacting the substrate with an APCC composition essentially consisting of
   (i) 0.1 to 3% by weight ammonia;
   (ii) a C₁ to C₄ alkanol;
(e) removing the composition from the substrate.

The composition according to the present invention are particularly useful for avoiding pattern collapse of non-photoresist patterns with high aspect ratios stacks (HARS).

### DETAILED DESCRIPTION OF THE INVENTION

The present invention is directed to the use of a composition particularly for manufacturing patterned materials comprising sub 50 nm sized features like integrated circuit (IC) devices, data storage devices, optical devices, micromachines and mechanical precision devices, in particular IC devices. The composition is also referred to herein as “anti pattern collapse composition” or, since ammonia is essentially dissolved in the C₁ to C₄ alkanol, simply “APCC solution”.

Any customary and known substrates used for manufacturing IC devices, optical devices, micromachines and mechanical precision devices can be used in the process of the invention.

Preferably, the substrate is a semiconductor substrate, more preferably a silicon wafer, which wafers are customarily used for manufacturing IC devices, in particular IC devices comprising ICs having LSI, VLSI and ULSI.

Herein and in the context of the present invention, the term “patterned material layer” refers to a layer supported on a substrate. The supported layer has a specific pattern preferably having line-space structures with a line width of 50 nm and below wherein the supporting substrate is typically a semiconductor substrate, e.g., a semiconductor wafer. Such line space structures may be but are not limited to pillars and lines. “Width” herein means the shortest distance from one end to the other end of a structure, e.g. 30 nm for a 30 nm×50 nm pillar or 30 nm×1000 nm line; or 40 nm for a pillar with a diameter of 40 nm. The term “patterned material layer having line-space dimensions with a line width of 50 nm or below” means that the patterned material comprises line-space structures with a line width of 50 nm but also line space structures with a line width smaller (narrower) than 50 nm. The ratio of the line width to the width of space between two adjacent lines is preferably lower than 1:1, more preferably lower than 1:2. Patterned material layers having such a low “line-width-to-space-width” ratio are known by the skilled person to require a very delicate handling during production.

The APCC solution is particularly suitable for treating substrates having patterned material layers having line-space dimensions with a line width of 50 nm and less, in particular, 32 nm and less and, especially, 22 nm and less, i.e. patterned material layers for the sub-22 nm technology nodes. The patterned material layers preferably have aspect ratios above 4, preferably above 5, more preferably above 6, even more preferably above 8, even more preferably above 10, even more preferably above 12, even more preferably above 15, even more preferably above 20. The smaller the line-space dimensions and the higher the aspect ratios are the more advantageous is the use of the composition described herein. The critical aspect ratio also depends on the substrate to be treated for anti pattern collapse. For example, since low-k dielectrics are more unstable and tend to collapse aspect ratios of 4 are already challenging.

### Ammonia

The composition comprises ammonia in an amount of from 0.1 to 3% by weight.

In a preferred embodiment, the amount of ammonia is of from 0.2 to 2.8% by weight, particularly of from 0.3 to 2.7% by weight, more particularly of from 0.5 to 2.5% by weight, even more particularly of from 0.8 to 2.2% by weight, most particularly of from 1.0 to 2.0% by weight.

To prepare the APCC compositions having the desired ammonia concentration fixed stock solutions are available in the market, e.g. a solution of 4% ammonia in IPA (available from TCI) or a 7N solution of ammonia in methanol (available from Acros), or may be prepared by bubbling ammonia through the respective solvent until the desired concentration is reached.

The ammonia concentration may then be adjusted as desired by adding respective amounts of the respective solvent.

### Solvent

The composition comprises a C₁ to C₄ alkanol (also referred to as “alkanol”). It is possible to use more than one, e.g. two or three, C₁ to C₄ alkanols but it is preferred to use only one C₁ to C₄ alkanol.

Preferably the alkanol is methanol, ethanol, 1-propanol or 2-propanol or mixtures thereof. Particularly preferred are methanol, 2-propanol, or mixtures thereof. Most particularly preferred is 2-propanol.

In a preferred embodiment the content of the C₁ to C₄ alkanol in the composition is from 98% by weight to 99.9% by weight and sums up with ammonia to 100% by weight of the composition.

### Composition

The composition essentially consists of ammonia and the alkanol. As used herein, “essentially consisting of” means that the content of other components does not influence the anti pattern collapse rate and characteristics of the composition. Depending on the nature of the other components this means that its content should be below 1% by weight, preferably below 0.5% by weight, more preferably below 0.1% by weight, most preferably below 0.01% by weight.

In a preferred embodiment, the anti pattern collapse cleaning (APCC) composition consists of the alkanol and ammonia essentially dissolved therein.

In another embodiment the composition is a homogeneous (one phase) composition.

Preferably the composition is non-aqueous. As used herein, “non-aqueous” means that the composition may only contain low amounts of water up to about 1% by weight. Preferably the non-aqueous composition comprises less than 0.5% by weight, more preferably less than 0.2% by weight, even more preferably less than 0.1% by weight, even more preferably less than 0.05% by weight, even more preferably less than 0.02% by weight, even more preferably less than 0.01% by weight, even more preferably less than 0.001% by weight. Most preferably essentially no water is present in the composition. “Essentially” here means that the water present in the composition does not have a significant influence on the performance of the additive in the non-aqueous composition with respect to pattern collapse of the substrates to be treated.

### Application

The composition according to the present invention may be applied to substrates of any patterned material as long as structures tend to collapse due to their geometry.

By way of example, the patterned material layers may be
(a) patterned silicon layers,
(b) patterned barrier material layers containing or consisting of ruthenium, titanium nitride, tantalum or tantalum nitride,
(c) patterned multi-stack material layers containing or consisting of layers of at least two different materials selected from the group consisting of silicon, polysilicon, low-k and ultra-low-k materials, high-k materials, semiconductors other than silicon and polysilicon, and metals, and
d) patterned dielectric material layers containing or consisting of low-k or ultra-low-k dielectric materials.

It is particularly preferred to apply the composition according to the invention to patterned silicon layers.

The method for manufacturing integrated circuit devices, electronic data storage devices, optical devices, micromachines and mechanical precision devices, comprises the steps described below.

In a first step (a) a substrate having patterned material layers having line-space dimensions with a line width of 50 nm or below, aspect ratios of greater or equal 4, or a combination thereof is provided.

The substrate is preferably provided by a photolithographic process comprising the steps of
(i) providing the substrate with an immersion photoresist, EUV photoresist or eBeam photoresist layer,
(ii) exposing the photoresist layer to actinic radiation through a mask with or without an immersion liquid,
(iii) developing the exposed photoresist layer with a developer solution to obtain a pattern having line-space dimensions with a line width of 32 nm and less and an aspect ratio of 4 or more,
(iv) spin drying the semiconductor substrate.

Any customary and known immersion photoresist, EUV photoresist or eBeam photoresist can be used. The immersion photoresist may already contain at least one of the siloxane additives or a combination thereof. Additionally, the immersion photoresist may contain other nonionic additives. Suitable nonionic additives are described, for example, in US 2008/0299487 A1, page 6, paragraph [0078]. Most preferably, the immersion photoresist is a positive resist.

Beside e-Beam exposure or extreme ultraviolet radiation of approx. 13.5 nm, preferably, UV radiation of the wavelength of 193 nm is used as the actinic radiation.

In case of immersion lithography preferably, ultra-pure water is used as the immersion liquid.

Any customary and known developer solution can be used for developing the exposed photoresist layer. Preferably, aqueous developer solutions containing tetramethylammonium hydroxide (TMAH) are used.

Customary and known equipment customarily used in the semiconductor industry can be used for carrying out the photolithographic process in accordance with the method of the invention.

In step (b) the substrate is contacted with an aqueous pretreatment composition comprising or essentially consisting of 0.1 to 2% by weight HF, preferably 0.25 to 1% by weight HF.

Preferably the pretreatment composition consists of water and HF. The pretreatment is usually performed for about 10 s to about 10 min, more preferably from about 20 s to about 5 min, most preferably from about 30 s to about 3 min.

In step (c) the pretreatment composition of step (b) is removed from the substrate. This is usually done by rinsing the substrate with ultrapure water. Preferably this step is preferably performed once, but may also be repeated, if required.

In step (d) the substrate is contacted with a solvent-based composition essentially consisting of the APCC solution described herein. This APCC treatment is usually performed for about 10 s to about 10 min, more preferably from about 20 s to about 5 min, most preferably from about 30 s to about 3 min.

Typically, all steps (a) to (d) may be used at any temperature from 10 to 40° C. or higher. If the temperature is higher, the compositions are not stable since the amount of ammonia will be quickly reduced by evaporation. A lower temperature is generally possible but would require intensive cooling. It is preferred that the temperature is from 10 to 35° C., even more preferred from 15 to 30° C.

In step (e) the solution is removed from the substrate. Any known methods customarily used for removing liquids from solid surfaces can be employed. In a preferred embodiment this is done by
(i) bringing the substrate into contact with a polar protic solvent, preferably a C₁ to C₄ alkanol, most preferably with 2-propanol, methanol or ethanol; and
(ii) evaporating the polar protic solvent of step (i), preferably in the presence of an inert gas. Preferably the inert gas is nitrogen.

All percent, ppm or comparable values refer to the weight with respect to the total weight of the respective composition except where otherwise indicated. All cited documents are incorporated herein by reference.

The following examples shall further illustrate the present invention without restricting the scope of this invention.

### EXAMPLES

Several experiments with solutions of ammonia in 2-propanol and methanol were conducted.

To prepare ammonia in 2-propanol (IPA) solutions of desired concentrations, desired amounts of a stock solution of 4% ammonia in IPA (available from TCI) were added to the beaker first. IPA was then added to make a solution of 100 g in total. The solution was then stirred at 300 rpm for at least 3 minutes prior to use.

To prepare ammonia in methanol solution of desired concentrations, desired amounts of a 7N stock solution of ammonia in methanol (available from Acros) were added to the beaker first. Methanol was then added to make a solution of 100 g in total. The solution was then stirred at 300 rpm for at least 3 minutes prior to use.

Patterned silicon wafers with a circular nano pillar pattern were used to determine the pattern collapse performance of the formulations during drying. The (aspect ratio) AR 20 pillars used for testing had a height of 600 nm and a diameter of 30 nm. The pitch size was 90 nm. 1×1 cm wafer pieces where processed in the following sequence without drying in between:
50 s Dilute Hydrofluoric Acid (DHF) 0.9% by weight dip,
60 s ultra-pure water (UPW) dip,
30 s 2-propanol (isopropanol, IPA) dip,
60 s dip with a composition consisting of ammonia and 2-propanol in an amount specified in table 1 at room temperature,
60 s IPA dip,
N₂ blow dry.

The dried silicon wafers where analyzed with top down SEM and the uncollaped rate are shown in Table 1. Since the collapse varies from center to edge only structures taken from essentially the same center edge distance were compared. In the experiments similar, if possible the same, stiffness values were chosen to assess the performance of the solution with respect to the uncollapsed rate. The pillar stiffness was 54 mN/m.

TABLE 1

| | NH₃ Conc. | | Conc. | Uncollapsed |
|---|---|---|---|---|
| Example | [wt %] | Solvent | [wt %] | pillars [%] |
| Comparative 1 | 0 | IPA | 100 | 18.3 |
| 2 | 0.10 | IPA | 99.9 | 25.3 |
| 3 | 0.20 | IPA | 99.8 | 35.5 |
| 4 | 0.50 | IPA | 99.5 | 41.1 |
| 5 | 1.00 | IPA | 99.0 | 48.3 |
| 6 | 2.00 | IPA | 98.0 | 53.7 |
| Comparative 7 | 0 | methanol | 100 | 24.0 |
| 8 | 0.50 | methanol | 99.5 | 46.9 |
| 9 | 1.00 | methanol | 99.0 | 44.6 |
| 10 | 2.00 | methanol | 98.0 | 51.4 |
| Comparative 11 | 0 | IPA + | 25 + 75 | 9.6 |
| | | ethyl acetate | | |
| Comparative 12 | 0 | IPA + | 25 + 75 | 7.5 |
| | | ethyl acetate | | |

Table 1 shows that example compositions 2 to 6 and 8 to 10 show a beneficial effect on the degree of pattern collapse compared to the composition with 2-propanol or methanol only.

In example 11 the 50 s dilute hydrofluoric acid (DHF) 0.9% by weight dip was omitted.

Comparative Examples 11 and 12 show some comparative experiments a with a solvent based anti pattern collapse composition according to WO 2019/224032 A. The compositions according to the present invention comprising ammonia show much higher rate of uncollapsed pillars than those of WO 2019/224032 A.

1. A method of using a composition, the composition comprising:
(a) 0.1 to 3% by weight ammonia; and
(b) a C₁ to C₄ alkanol,
the method comprising using the composition for anti-pattern collapse treatment of a substrate comprising patterned material layers having line-space dimensions with a line width of 50 nm or less, aspect ratios of greater than or equal to 4, or combination thereof.

2. The method according to claim 1, wherein an amount of the C₁ to C₄ alkanol in the composition is from 98% to 99.9% by weight and sums up with ammonia to 100%.

3. The method according to claim 1, wherein the C₁ to C₄ alkanol is selected from the group consisting of methanol, ethanol, 1-propanol, and 2-propanol.

4. The method according to claim 1, wherein an amount of ammonia in the composition is from 0.5 to 2.5% by weight.

5. The method according to claim 1, wherein the substrate comprises patterned material layers having line-space dimensions with a line width of 32 nm or less and aspect ratios of greater than or equal to 8.

6. A method for manufacturing integrated circuit devices, electronic data storage devices, optical devices, micromachines, and mechanical precision devices, the method comprising the steps of:
(a) providing a substrate comprising patterned material layers having line-space dimensions with a line width of 50 nm or less, aspect ratios of greater than or equal to 4, or a combination thereof;
(b) contacting the substrate with an aqueous pretreatment composition comprising 0.1 to 2% by weight HF;
(c) removing the aqueous pretreatment composition from the substrate;
(d) contacting the substrate with an APCC composition comprising:
(i) 0.1 to 3% by weight ammonia; and
(ii) a C₁ to C₄ alkanol; and
(e) removing the APCC composition from the substrate.

7. The method according to claim 6, wherein the aqueous pretreatment composition consists essentially of water and HF.

8. The method according to claim 6, wherein an amount of the C₁ to C₄ alkanol in the composition is from 98% to 99.9% by weight and sums up with ammonia to 100%.

9. The method according to claim 6, wherein the C₁ to C₄ alkanol is selected from the group consisting of methanol, ethanol, 1-propanol, and 2-propanol.

10. The method according to claim 6, wherein an amount of ammonia in the APCC composition is from 0.5 to 2.5% by weight.

11. The method according to claim 6, wherein the APCC composition is removed from the substrate by:
(i) bringing the substrate into contact with a polar protic solvent; and
(ii) evaporating the polar protic solvent.

12. The method according to claim 6, wherein step (a) comprises:
(i) providing the substrate with an immersion photoresist layer, an EUV photoresist layer, or an eBeam photoresist layer,
(ii) exposing the photoresist layer to actinic radiation through a mask with or without an immersion liquid,
(iii) developing the exposed photoresist layer with a developer solution to obtain a pattern having line-space dimensions with a line width of 50 nm or less and an aspect ratio of 4 or more, and
(iv) spin drying the substrate.

13. The method according to claim 6, wherein any of the steps (a), (b), (c) or (d) is performed for 20 s to 5 min.

14. The method according to claim 6, wherein the patterned material layers have line-space dimensions with a line width of 32 nm or less and aspect ratios of 8 or more.

15. The method according to claim 6, wherein the patterned material layers are selected from the group consisting of patterned silicon layers, patterned barrier material layers, patterned multi-stack material layers, and patterned dielectric material layers.

16. The method according to claim 1, wherein the C₁ to C₄ alkanol is selected from the group consisting of methanol and 2-propanol.

17. The method according to claim 1, wherein an amount of ammonia in the composition is from 1.0 to 2.0% by weight.

18. The method according to claim 6, wherein contacting the substrate with an aqueous pretreatment composition comprises contacting the substrate with an aqueous pretreatment composition comprising 0.25 to 1% by weight HF.

19. The method according to claim 6, wherein the C₁ to C₄ alkanol is selected from the group consisting of methanol and 2-propanol.

20. The method according to claim 6, wherein an amount of ammonia in the APCC composition is from 1.0 to 2.0% by weight.
